(19) United States
(12) Patent Application Publication
(10) Pub. No.: US 2007/0018191 A1
(43) Pub. Date: Jan. 25, 2007

(54) Side view LED with improved arrangement of protection device

(75) Inventors: Jae Ky Roh, Suwon (KR); Seong Jae Hong, Yongin (KR); Chang Wook Kim, Anyang (KR); Young Jae Song, Suwon (KR); Yoon Suk Han, Seoul (KR)

Correspondence Address: MCDERMOTT WILL & EMERY LLP, 600 13TH STREET, N.W., WASHINGTON, DC, 20005-3096, US

(73) Assignee: Samsung Electro-Mechanics Co., Ltd.

(21) Appl. No.: 11/490,233

(22) Filed: Jul. 21, 2006

(30) Foreign Application Priority Data
Jul. 22, 2005 (KR) 10-2005-0066848

(51) Int. Cl. H01L 33/00

(52) U.S. Cl. 257/99; 257/100; 257/E33.058

(57) ABSTRACT

A side view LED includes an insulating substrate, and first and second metal layers each having first and second areas spaced apart from each other at a predetermined gap and disposed on top and underside surfaces of the insulating substrate, respectively. First and second electrical connectors are formed in a thickness direction of the insulating substrate, connecting the first area of the first metal layer to that of the second metal layer, and the second area of the first metal layer to that of the second metal layer. An LED chip is mounted on the first metal layer and electrically connected to the first and second areas. Also, a wall part is attached to the first metal layer to form an opened area around the LED chip. A protective device is mounted on an underside surface of the second metal layer and electrically connected to the first and second areas.

### CLAIM OF PRIORITY

This application claims the benefit of Korean Patent Application No. 2005-66848 filed on Jul. 22, 2005 in the Korean Intellectual Property Office, the disclosure of which is incorporated herein by reference.

### BACKGROUND OF THE INVENTION

1. Field of the Invention

The present invention relates to a side view Light Emitting Diode (LED) for use in a backlight device. More particularly, the present invention relates to a side view LED which has metal layers formed on top and underside surfaces of a substrate and an LED chip and a protective device mounted on the top and underside surfaces thereof, respectively, in order to prevent light absorption by the protective device, thereby enhancing light emitting efficiency, and to overcome productivity decline resulting from arrangement of the LED chip and protective device in the same location.

2. Description of the Related Art

A small Liquid Crystal Device (LCD) used in mobile phones, Personal Digital Assistants (PDAs) and the like employs a side-view Light Emitting Diode (LED) as a light source for its backlight device. Such a side view LED is typically mounted in the backlight device as shown in FIG. 1.

Referring to FIG. 1, the backlight device 50 has a flat light guide plate 54 formed on a substrate 52. Also, a plurality of side-view LEDs 1 (only one LED illustrated) are arrayed on a side of the light guide plate 54. Light L incident into the light guide plate 54 from the LEDs is reflected upward by a reflective sheet 56 or microdot patterns formed on the light guide plate 54. Then the light L exits from the light guide plate 54 to provide a backlight to an LCD panel 58 over the light guide panel 54.

The LED is purportedly susceptible to static electricity, inverse voltage or over voltage. Especially, the side view LED needs to be extremely thin and accordingly an LED chip mounted is downscaled. This renders the LED greatly affected by undesired effects of current/voltage so that it is imperative to prevent them.

To this end, a voltage regulation diode is provided to the LED. That is, the voltage regulation diode is connected to the LED chip in parallel to effectively counter static electricity. Preferably, the voltage regulation diode is exemplified by a Zener diode.

Then, a detailed explanation will be given about a conventional side view LED having a Zener diode mounted therein with reference to FIGS. 2 and 3.

FIG. 2 is a front elevation view illustrating the side view LED having the Zener diode mounted therein according to the prior art. FIG. 3 is a cross sectional view cut along the line 3-3 of FIG. 2.

As shown in FIGS. 2 and 3, the conventional LED 1 includes a package body 10, a pair of leads 20 and 22 spaced apart from each other at a predetermined gap and an LED chip 30 mounted on the leads 20.

The LED chip 30 is connected to the leads 20 and 22 via wires 32 and encapsulated by a transparent encapsulant 14 provided into a cup-shaped concave 12 therearound.

Meanwhile, a Zener diode 40 is mounted on the lead 22 and connected thereto via a wire 34. In this fashion, the Zener diode 40 is connected to the LED chip 30 in parallel, thereby protecting the LED chip 30 from static electricity, inverse voltage or over voltage.

The Zener diode 40, which belongs to a semiconductor PN junction diode, is structured such that it operates in a breakdown area of the PN junction. Thus the Zener diode 40 is chiefly used for voltage regulation or to ensure a constant voltage. The Zener diode 40 obtains a predetermined voltage via a zener recovery phenomenon. Also the Zener diode 40 operates at a current of 10 mA when having a p-n junction of silicon and may produce a constant voltage of 3 to 12 V depending on its type.

However, in the conventional LED 1, the Zener diode 40 is coplanarly disposed with the LED chip 30 in parallel so that light generated from the LED chip is absorbed or scattered by the Zener diode 40, thereby degrading light emitting efficiency of the LED 1.

Also, with the LED chip 30 and Zener diode 40 disposed in the narrow concave 12, the wires 32 and 34 should be disposed at a predetermined gap so that they do not contact one another. This requires a meticulous and deliberate process and accordingly undermines efficiency in fabricating the LED.

### SUMMARY OF THE INVENTION

The present invention has been made to solve the foregoing problems of the prior art and therefore an object according to certain embodiments of the present invention is to provide a side view LED which has metal layers formed on top and underside surfaces of a substrate and an LED chip and a protective device mounted on the top and underside surfaces thereof, respectively, in order to prevent light absorption by the protective device, thereby improving light emitting efficiency, and to overcome productivity decline resulting from arrangement of the LED chip and protective device in the same location.

According to an aspect of the invention for realizing the object, there is provided a side view light emitting diode comprising: an insulating substrate; first and second metal layers each having first and second areas spaced apart from each other at a predetermined gap, the metal layers disposed on top and underside surfaces of the insulating substrate, respectively; first and second electrical connectors formed in a thickness direction of the insulating substrate, the first electrical connector connecting the first area of the first metal layer to that of the second metal layer, and the second electrical connector connecting the second area of the the first metal layer to that of the second metal layer; a light emitting diode chip mounted on the first metal layer and electrically connected to the first area of the first metal layer and to the second area of the first metal layer; a wall part attached to the first metal layer to form an opened area around the light emitting diode chip; a transparent encapsulant provided in the opened area of the wall part to encapsulate the light emitting diode chip; a protective device mounted on an underside surface of the second metal layer and electrically connected to the first and second areas of the second metal layer to protect the light emitting diode chip from electrical abnormality; and an encapsulant attached to the second metal layer to encapsulate the protective device.

The side view light emitting diode further comprises an adhesive layer interposed between the wall part and the first metal layer.

The wall part comprises a resin injection-molded on the first metal layer.

The side view light emitting diode further comprises a second insulating substrate provided underneath the second metal layer with an opened area formed around the protective device, wherein the encapsulant is provided in the opened area of the second insulating substrate to encapsulate the protective device. At this time, the side-view light emitting diode may further comprise an adhesive layer interposed between the second substrate and the second metal layer.

Also, the first or second electrical connector is shaped as a cylinder cut along a length direction such that an inner surface of the cylinder is exposed to the outside.

The encapsulant of the protective device comprises one selected from a group consisting of a transparent resin, an opaque resin and a semitransparent resin.

The first or second electrical connector is a via. The first or second electrical connector is formed by filling metal powder and then sintering or reflowing the same.

In addition, each of the first and second metal layers has at least a portion thereof exposed to the outside to supply external power to the light emitting diode chip.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a side cross-sectional view illustrating a backlight device employing a side view LED according to the prior art;

FIG. 2 is a front elevation view illustrating a side view LED having a Zener diode mounted therein according to the prior art;

FIG. 3 is a cross-sectional view cut along the line 3-3 of FIG. 2;

FIG. 4 is a front elevation view illustrating a side view LED according to an embodiment of the invention;

FIG. 5 is a cross-sectional view cut along the line 5-5 of FIG. 4;

FIG. 6 is a cross-sectional view cut along the line 6-6 of FIG. 4;

FIGS. 7 and 8 are cross-sectional views illustrating a process for fabricating a side view LED according to an embodiment of the invention;

FIG. 9 is a cross-sectional view illustrating a side view LED corresponding to FIG. 5 according to another embodiment of the invention;

FIGS. 10 and 11 are cross-sectional views illustrating a process for fabricating a side view LED according to another embodiment of the invention;

FIG. 12 is a plan view corresponding to FIG. 10 (b);

FIG. 13 is a cross-sectional view illustrating a side view LED corresponding to FIG. 5 according to further another embodiment of the invention; and

FIGS. 14 and 15 are cross-sectional views illustrating a process for fabricating a side view LED according to further another embodiment of the invention.

### DETAILED DESCRIPTION OF THE PREFERRED EMBODIMENT

Preferred embodiments of the present invention will now be described in detail with reference to the accompanying drawings.

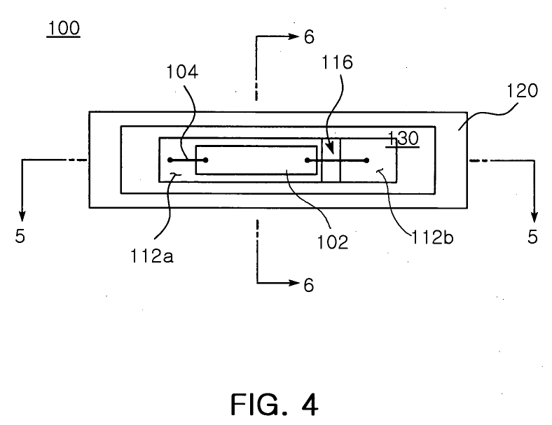

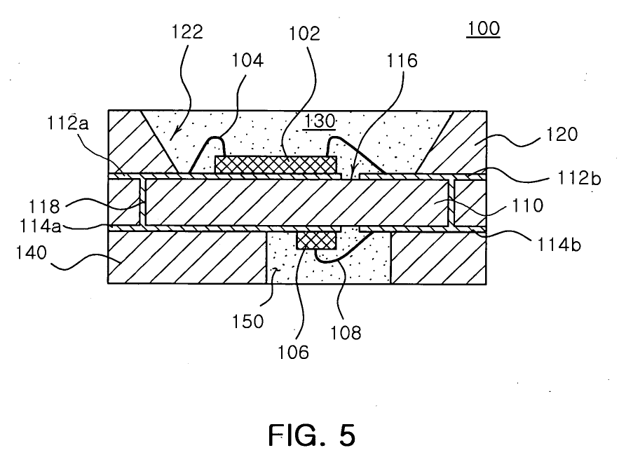

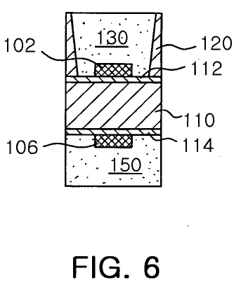

A side view LED will be explained according to an embodiment of the invention with reference to FIGS. 4 and 5, in which FIG. 4 is a front elevation view illustrating a side view LED according to the embodiment of the invention, and FIG. 5 is a cross-sectional view cut along the line 5-5 of FIG. 4. FIG. 6 is a cross-sectional view cut along the line 6-6 of FIG. 4.

The side view LED 100 according to the embodiment of the invention is characterized by a three-layer structure. That is, the side view LED 100 includes a first substrate 110 as a middle layer, a wall part 120 and a transparent encapsulant 130 disposed over the first substrate 110, and a second substrate 140 and an encapsulant 150 disposed under the first substrate 110.

The first substrate 110 is made of an insulating material and coated with first and second metal layers 112 and 114 on top and underside surfaces thereof. The first metal layer 112 is separated into a first area 112a (as shown in the left side of FIG. 5) and a second area 112b (as shown in the right side of FIG. 5) at a predetermined gap 116. Also, the second metal layer 114 is separated into a first area 114a (as shown in the left side of FIG. 5) and a second area 114b (as shown in the right side of FIG. 5) at a predetermined gap 116. Electric connectors 118 are formed in a predetermined area of the substrate in a thickness direction. A first area 112a of the first metal layer 112 is connected to a first area 114a of the second metal layer 114 via the electric connectors 118. Likewise, a second area 112b of the first metal layer 112 is connected to a second area 114b of the second metal layer 114 via the electric connectors 118. To form the electric connectors 118, holes are perforated in the first substrate 110, and a conductive material, e.g., metal powder is filled therein and then reflowed, sintered or plated.

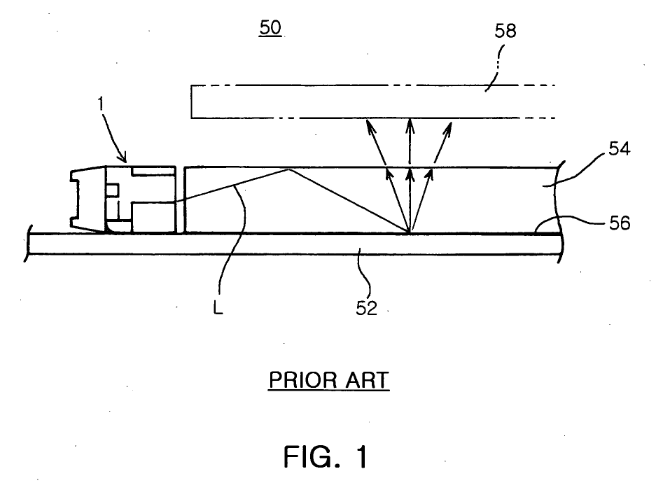

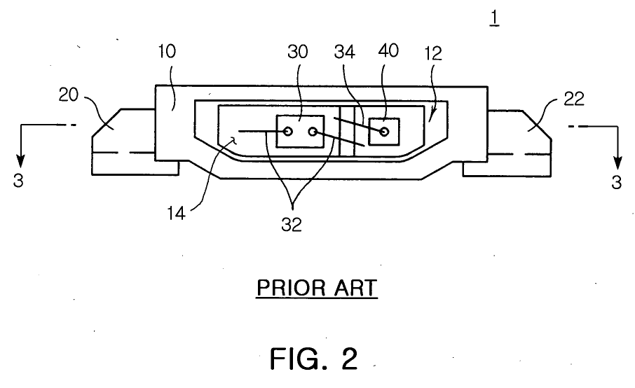

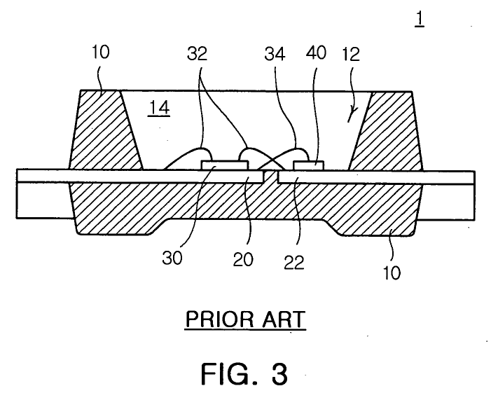

As shown in FIG. 6, the first and second metal layers 112 and 114 each extend to a side of the side view LED 100 (top and underside surfaces of the first substrate) to be exposed to the outside. Therefore, in the LED 100 of the invention, when mounted as in FIG. 1, for example, the first areas 112a and 114a of the first and second metal layers 112 and 114 serve as an input terminal while the second areas 112b and 114b thereof serve as an output terminal, thereby connected to electric lines (not illustrated) formed on the substrate 52 of the backlight device 52. Of course, the vice versa is applicable as well.

An LED chip 102 is mounted on the first metal layer 112 and electrically connected to the first and second areas 112a and 112b of the first metal layer via wires 104.

The wall part 120 is disposed around the LED chip 102 to form an opened area 122. In the opened area 122, an encapsulatnt 130 made of a transparent resin is provided to encapsulate the LED chip 102.

To form the wall part 120, holes are perforated on the first insulating substrate 110 to serve as the opened area 122, and then adhered to the first metal layer 112. Alternatively, resin may be injection-molded on the first metal layer 112 to form the wall part 120. In either case, the wall part 120 is made of preferably an opaque material, and more preferably a high reflectivity material. Of course, the wall part 120 may be made of a transparent material and its inner surface contacting the opened area 122 may be coated with an opaque or high reflectivity material.

The transparent encapsulant 130 is formed of various resins. The transparent encapuslant 130 is made of epoxy or silicone, and may contain an ultraviolet ray absorbent for absorbing ultraviolet rays generated in the LED chip 102 and fluorescent material for converting a monochromatic light into a white light.

A protective device 106 is mounted on the second metal layer 114 opposing the LED chip 102 and electrically connected to the second area 114b of the second metal layer 114 via wires 108. Here, the other electrode of the protective device 106 is directly connected to the first area 114a of the second metal layer 114. In this fashion, the protective device 106 is connected to the LED chip 102 in parallel, thereby protecting the LED chip 102 from electrical abnormality i.e., static electricity, inverse voltage and over voltage. The protective device 106 is exemplified by a voltage regulation diode such as a Zener diode.

The second substrate 140 is attached to the second metal layer 114 to form an opened area around the protective device 106. Also, resin is filled in the opened area of the second substrate 140 to encapsulate the second substrate 140, thereby forming the encapsulant 150. Unlike the aforesaid transparent encapsulant 130, the encapsulant 150 is not necessarily transparent.

The first metal layer 112, when structured in this fashion, acts as a reflector so that light generated in the LED chip 102 can be effectively emitted. Also, the protective device 106 opposing the LED chip 102 enhances light emitting efficiency due to no light absorbed. In addition, arrangement of the protective device 106 and the LED chip 103 in different locations complicates less and facilitates more a manufacturing process. Further, a plurality of substrates used renders the LED more easily fabricatable and mass-producible than in a case where a resin mold is employed.

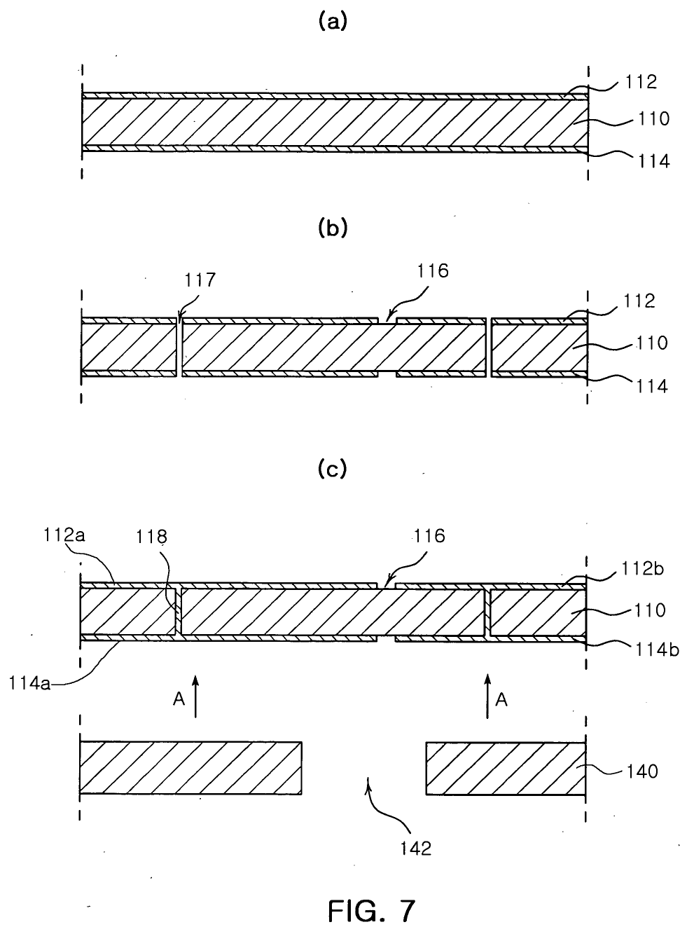

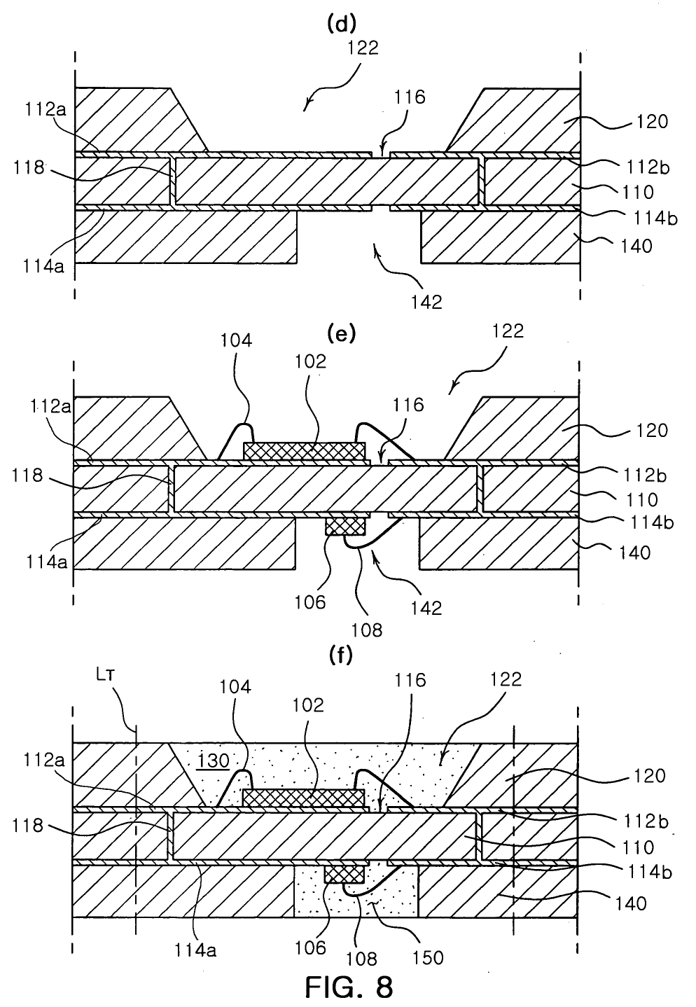

An explanation will be given about a method for fabricating a side view LED according to an embodiment of the invention with reference to FIGS. 7 and 8.

First, as shown in FIG. 7 (a), a first insulating substrate 110 is prepared, in which first and second metal layers 112 and 114 have been formed. Of course, this structure can be obtained by forming the first and second metal layers on top and underside surfaces of the insulating substrate.

Then, as shown in FIG. 7 (b), holes 117 are formed in a predetermined area to perforate the first and second metal layers 112 and 114 and the first substrate 110. The holes 117 can be perforated via drilling or punching. Next, the first and second metal layers 112 and 114 are partially removed in a predetermined area between the holes 117 to form a gap 116. Preferably, etching is employed to partially remove the metal layers. Alternatively, the perforation may be preceded by the gap-forming process.

Thereafter, metal powder is filled in the holes 117 and electric connectors 118 are formed via reflow or sintering. A left portion of the first metal layer 112, i.e., a first area 112a of the first metal layer is connected to a left portion of the second metal layer 114, i.e., a first area 114a of the second metal layer via the electric connectors 118. Likewise, a second area 112b of the first metal layer is connected to a second area 114b of the second metal layer via the electric connectors 118.

Next, as shown in FIG. 7 (c), a hole 142 is perforated to a predetermined size on a second insulating substrate 140 having a predetermined thickness. Then the first substrate 10 is attached to the second substrate 140 in an arrow A direction. At this time, an adhesive is applied in advance onto the first and second areas 114a and 114b, which will be attached to the second substrate 140. This allows the first and second substrates 110 and 140 to be easily bonded together.

Then, as shown in FIG. 8 (d), a substrate is prepared, in which holes have been perforated to a predetermined size and shape. Of course, the holes may be perforated to a predetermined size and shape on the substrate. Then the substrate is attached to the first metal layer 112a and 112b. The attached substrate forms a wall part 120 having an opened area 122. The adhesive is applied in advance onto an underside of the substrate to ensure its effective bonding with the first and second metal layers 112a and 112b. Alternatively, resin may be injected to form the wall part 120. In either case, the wall part 120 is made of preferably an opaque resin, and more preferably a high reflectivity resin.

Then as shown in FIG. 8 (e), an LED chip 102 is mounted on the first area 112a of the first metal layer in the opened area 122 adjoining the wall part 120. Then the LED chip 102 is connected to the first and second areas 112a and 112b of the first metal layer via wires 104. Next, a protective device 106 is mounted underneath the first area 114a of the second metal layer and connected to the second area 114b of the second metal layer via wires 104. Meanwhile, the other electrode of the protective device 106 is connected to the first area 114a of the second metal layer. This allows the protective device 106 to be disposed opposite to the LED chip 102, connected in parallel. Of course, the protective device 106 can be mounted prior to the LED chip 102. Alternatively, the LED chip 102 is flip-bonded to the first and second areas 112a and 112b of the first metal layer.

Then, as shown in FIG. 8 (f), a transparent resin is poured into the opened area adjoining the wall part 120 and cured to form a transparent encapsulant 130 for encapsulating the LED chip 102. The transparent encapsulant 130 is made of a transparent silicone or epoxy. In addition, resin is poured into the opened area 142 of the second substrate 140 and cured to form an encapsulant 150 for encapsulating the protective device 106. Unlike the transparent encapsulant 130, the encapsulant 150 is made of various resins such as a transparent, opaque or semi-transparent resin.

This structure of FIG. 8 (f), when cut along a cutting line LT, produces a unit LED 100 as shown in FIG. 5.

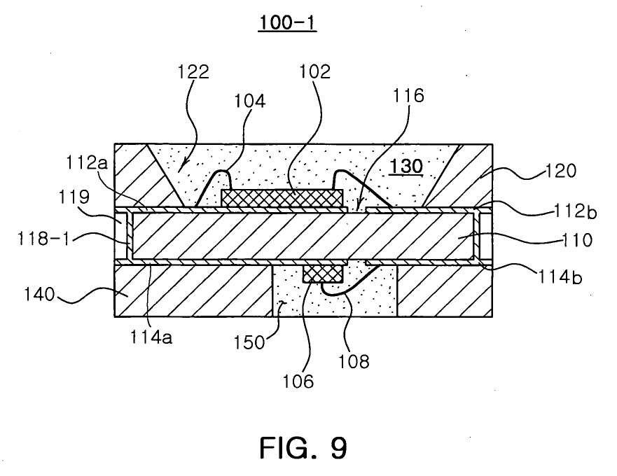

An explanation will be given about a side view LED according to another embodiment of the invention with reference to FIG. 9, which is a cross-sectional view illustrating the side view LED 100-1 corresponding to FIG. 5 according to the embodiment of the invention.

The side view LED 100-1 of FIG. 9 is substantially identical to the aforesaid side view LED 100. The only difference is that in the side view LED 100-1 of FIG. 9, the first area 112a of the first metal layer is connected to the first area 114a of the second metal layer by a quarter-cylindrical electrical connector 118-1 in place of a via-shaped electric connector, and a quarter-cylindrical groove 119 is formed in an exterior of the electric connector. Therefore, the same or corresponding components were given the same reference signs and will not be explained further.

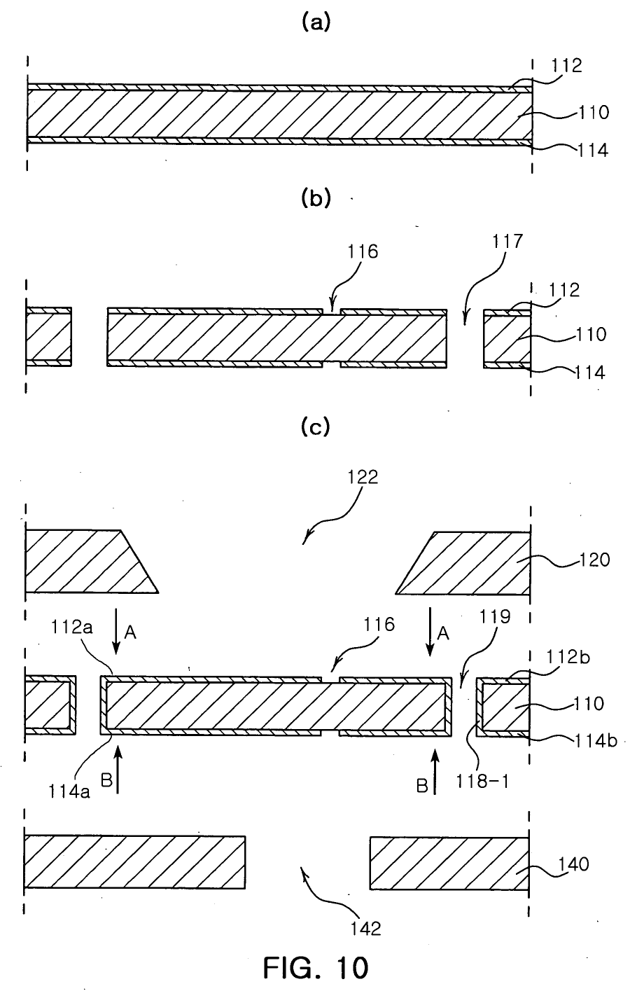

Then functions of the electric connector 118-1 and groove 119 will be explained hereunder. The side view LED 100-1, when employed in a backlight, is mounted as in FIG. 1. With reference to FIG. 10, the side view LED 100-1 will be mounted as indicated with bold lines. Here, holes 117 correspond to areas for forming the electric connector 118-1 and groove 119. At this time, to obtain the electric connector 118-1, a metal layer is formed on an inner wall of the holes 117 via plating or deposition.

Accordingly, the electric connector 118-1 and groove 119 face toward a backlight substrate 52. Also, the first areas 112a and 114a of the first and second layers or second areas 12b and 114b of the first and second layers are connected to wires of the backlight substrate 52 via soldering. This allows the groove 119 to partially absorb solder in the soldering, thereby enhancing bonding between the LED 100-1 and the backlight substrate 52.

These characteristics and advantages are peculiar to the LED 100-1 according to this embodiment of the invention. Moreover, since the LED 100-1 of this embodiment is substantially identical to the aforesaid LED 100 except for the aspects just described, the LED 100-1 also exhibits advantages and effects of the LED 100.

A method for fabricating the LED 100-1 will be explained hereunder with reference to FIGS. 10, 11 and 12.

First, as shown in FIG. 10 (a), a first insulating substrate 110 having metal layers 112 and 114 disposed on top and underside surfaces thereof, respectively, is prepared. Of course, to obtain this structure, first and second metal layers can be formed on the top and underside surfaces of the insulating substrate.

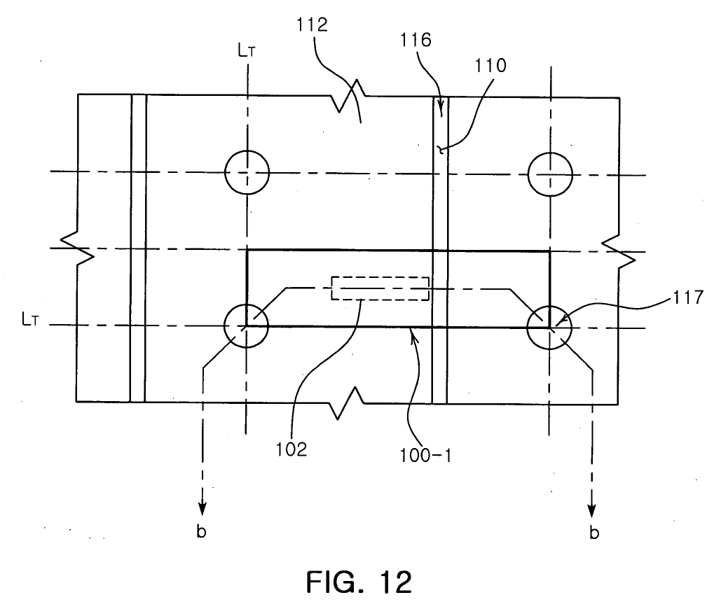

Then, as shown in FIG. 10 (b), holes 117 are formed in a predetermined area to perforate the first and second metal layers 112 and 114 and the first substrate 110. The holes 117 are perforated via drilling or punching and in a sufficiently large diameter for deposition or plating, which will follow. Then the first and second metal layers 112 and 114 are partially removed in a predetermined area between the holes 117 to form a gap 116. Preferably, etching is employed to partially remove the metal layers 112 and 114. FIG. 12 is a top view illustrating the substrate having the holes 117 and the gap 116. In FIG. 12, for the sake of convenience, a final LED 100-1 area is indicated with a bold line and an LED chip 102 is indicated with a dotted line. Meanwhile, the perforation may be preceded by a gap-forming process.

Thereafter, as shown in FIG. 10 (c), a metal layer is formed on an inner wall of the holes 117 via deposition or plating to form cylindrical electrical connectors 118. In the following processes, reference sign 117 of the holes 117 is replaced by reference sign 119. A left portion of the first metal layer 112, i.e., a first area 112a of the first metal layer is connected to a left portion of the second metal layer 114, i.e., a second area 114a of the second metal layer via the electric connectors 118. Likewise, a second area 112b of the first metal layer is connected to a second area 114b of the second metal layer via the electric connectors 118.

Next, a hole 142 is perforated to a predetermined size in a second insulating substrate 140 having a predetermined thickness. The second substrate 140 is attached to the first substrate 110 in an arrow B direction. At this time, an adhesive is applied in advance onto the first and second areas 114a and 114b of the second metal layer, which is attached to the second substrate 140, thereby ensuring the first and second substrates 110 and 140 to be easily bonded together.

Then a substrate is prepared, in which holes have been perforated to a predetermined size and shape. Of course, the holes may be perforated to a predetermined size and shape in the substrate. Then the substrate is attached to the first metal layers 112a and 112b in an arrow A direction. The attached substrate forms a wall part 120 having an opened area 122. At this time, the adhesive is applied in advance onto an underside surface of the substrate, thereby ensuring the substrate to be effectively bonded to the first metal layers 112a and 112b. Alternatively, resin may be injected to form the wall part 120.

Here, the bonding of the second substrate 140 may be preceded by forming of the wall part 120.

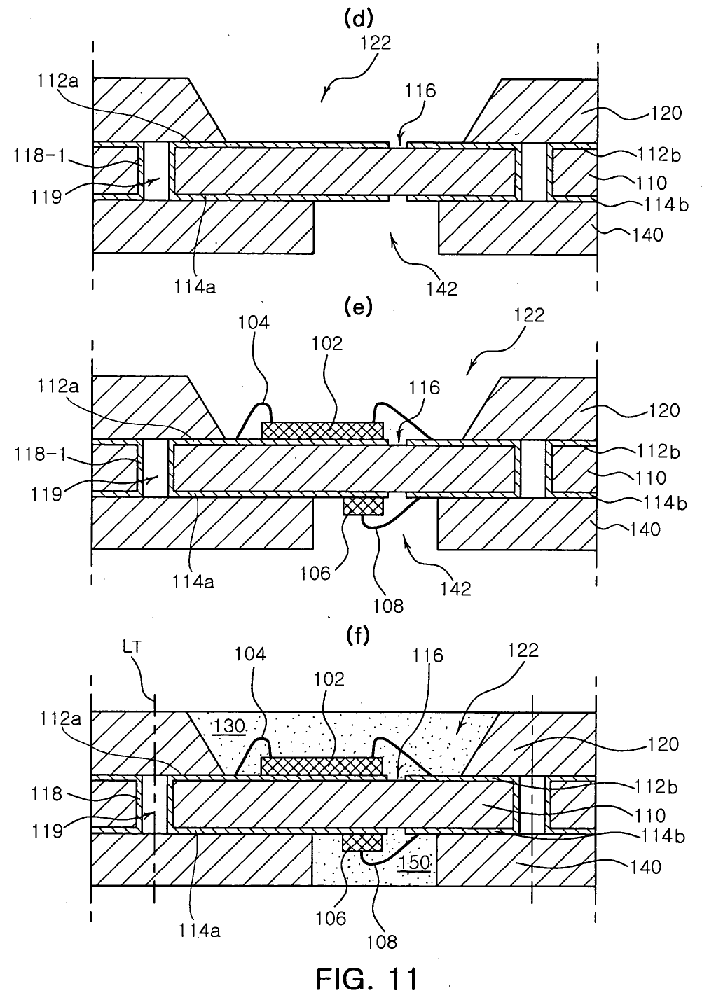

FIG. 11 (d) illustrates such an LED structure in which the second substrate 140 is attached and the wall part 120 is formed.

A process of FIG. 11 (e) is substantially identical to the aforesaid process of FIG. 8 (e).

A process of FIG. 11 (f) is also substantially identical to that of FIG. 8 (f) regarding forming of the transparent encapsulant 130 and an encapsulant 150. The only difference is that if the structure obtained is cut along a cutting line LT, a cylindrical electrical connector 118 is divided into quarters as in FIG. 12, thereby producing a quarter-cylindrical electrical connector 118-1 as in FIG. 9.

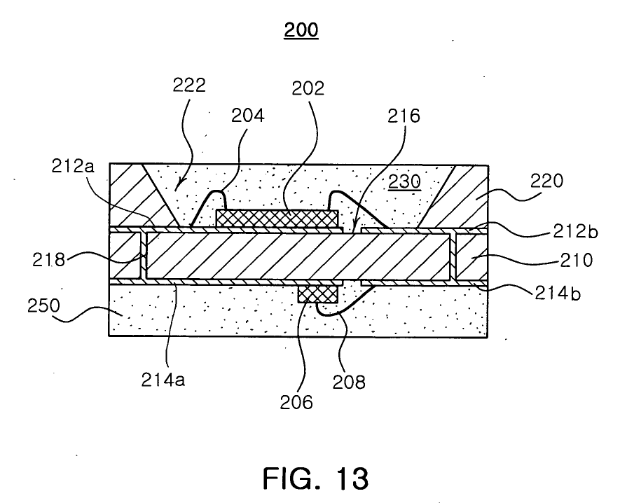

An explanation will be given about a side view LED according to further another embodiment of the invention with reference to FIG. 13.

The side view LED 200 shown in FIG. 13 is substantially identical to the aforesaid side view LED 100 except that an encapsulant 250 is provided underneath an entire portion of second metal layers 214a and 214b to encapsulate a protective device. Therefore, similar or corresponding components were given reference signs that increased by 100s and will not be explained further.

To form the encapsulant 250, a transparent resin, an opaque resin or a semi-transparent resin is injection-molded. Alternatively, unlike FIG. 13, the encapsulant may be shaped as a dome, hemisphere or semi-ellipse to encapsulate only a protective device 206 and wires 208.

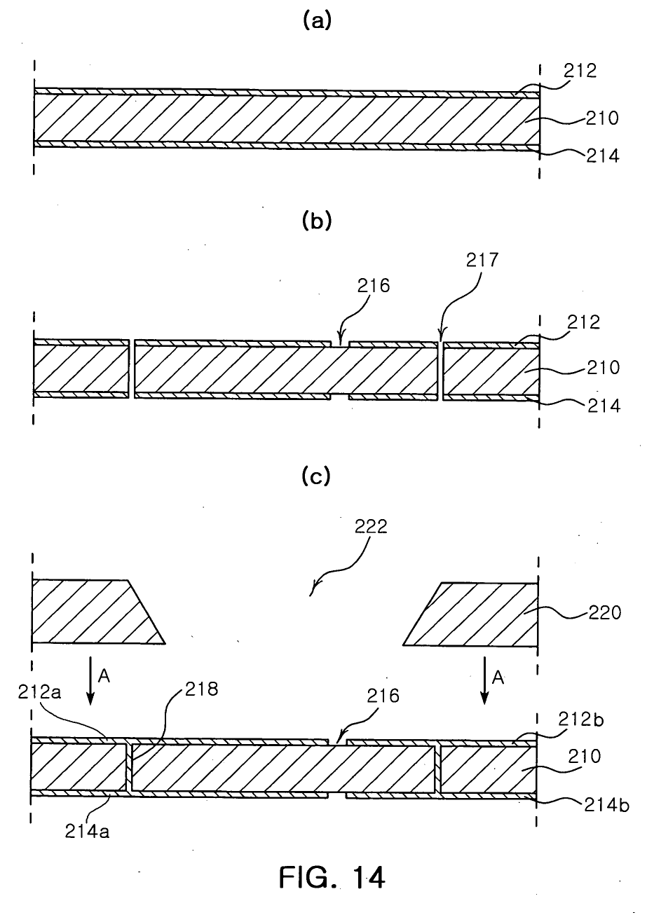

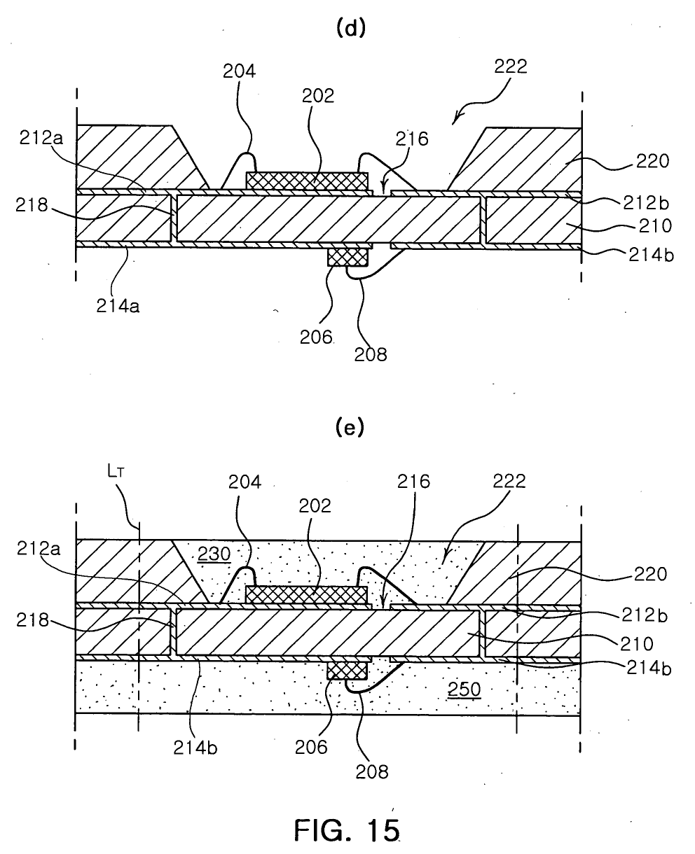

Then, a process for fabricating an LED 200 will be explained with reference to FIGS. 14 and 15.

Processes of FIGS. 14 (a) and (b) are substantially identical to those of FIGS. 7(a) and 7(b).

As shown in FIG. 14 (c), a substrate is prepared, in which holes have been perforated to a predetermined size and shape. Of course, the holes may be perforated to a predetermined size and shape on the substrate. The substrate is attached to the first metal layers 212a and 212b in an arrow A direction. The attached substrate forms a wall part 220 having an opened area 222. Here, an adhesive is applied in advance onto an underside of the substrate, thereby ensuring the substrate to be effectively bonded to the first metal layers 212a and 212b. Alternatively, resin may be injected to form the wall part 220.

Thereafter, as shown in FIG. 15 (d), an LED chip 202 is mounted on the first area 212a of the first metal layer in the opened area 222 adjoining the wall part 220, and then connected to the first and second areas 212a and 212b of the first metal layer via wires 204. Then, a protective device 206 is mounted on the first area 214a of the second metal layer opposing the LED chip 202, and then connected to the second area 214b of the second metal layer via the wires 204. Meanwhile, the other electrode of the protective device 206 is directly connected to the first area 214a of the second metal layer. This allows the protective device 206 to be connected in parallel to the opposing LED chip 202. Here, the protective device 206 may be mounted first before the LED chip 202. Alternatively, the LED chip 202 is flip-bonded to the first and second areas 21a and 212b of the first metal layer.

As shown in FIG. 15 (e), a transparent resin is poured into the opened area 222 of the wall part 220 and cured, thereby forming a transparent encapsulant 230 for encapsulating the LED chip 202. The transparent encapsulant 230 is made of a transparent silicone or epoxy. In addition, an encapsulant 250 is formed via injection-mold to encapsulate the protective device 206. The encapsulant 250, unlike the transparent encapsulant 230, may be made of various resins such as a transparent, opaque or semi-transparent resin. Alternatively, the encapsulant 250 may be shaped as a dome, hemisphere or semi-ellipse to encapsulate only the protective device 206 and wires 208.

This structure of FIG. 15 (e), when cut along a cutting line LT, produces a unit LED 200 as shown in FIG. 13.

As set forth above, according to preferred embodiments of the invention, a first metal layer serves as a reflector so that light generated from an LED chip can be effectively emitted. Also, a protective device opposing the LED chip enhances light emitting efficiency due to no light absorbed. Arrangement of the protective device and the LED chip at different locations complicates less and facilitates further a fabrication process. In addition, a plurality of substrates stacked render the LED more easily fabricatable and mass-producible than in a case where resin is molded.

While the present invention has been shown and described in connection with the preferred embodiments, it will be apparent to those skilled in the art that modifications and variations can be made without departing from the spirit and scope of the invention as defined by the appended claims.

What is claimed is:

1. A side view light emitting diode comprising:
an insulating substrate;
first and second metal layers each having first and second areas spaced apart from each other at a predetermined gap, the metal layers disposed on top and underside surfaces of the insulating substrate, respectively;
first and second electrical connectors formed in a thickness direction of the insulating substrate, the first electrical connector connecting the first area of the first metal layer to that of the second metal layer, and the second electrical connector connecting the second area of the the first metal layer to that of the second metal layer;
a light emitting diode chip mounted on the first metal layer and electrically connected to the first area of the first metal layer and to the second area of the first metal layer;
a wall part attached to the first metal layer to form an opened area around the light emitting diode chip;
a transparent encapsulant provided in the opened area of the wall part to encapsulate the light emitting diode chip;
a protective device mounted on an underside surface of the second metal layer and electrically connected to the first and second areas of the second metal layer to protect the light emitting diode chip from electrical abnormality; and
an encapsulant attached to the second metal layer to encapsulate the protective device.

2. The side view light emitting diode according to claim 1, further comprising an adhesive layer interposed between the wall part and the first metal layer.

3. The side view light emitting diode according to claim 1, wherein the wall part comprises a resin injection-molded on the first metal layer.

4. The side view light emitting diode according to claim 1, further comprising a second insulating substrate provided underneath the second metal layer with an opened area formed around the protective device,
wherein the encapsulant is provided in the opened area of the second insulating substrate to encapsulate the protective device.

5. The side-view light emitting diode according to claim 4, further comprising an adhesive layer interposed between the second substrate and the second metal layer.

6. The side view light emitting diode according to claim 1, wherein the first or second electrical connector is shaped as a cylinder cut along a length direction such that an inner surface of the cylinder is exposed to the outside.

7. The side view light emitting diode according to claim 1, wherein the encapsulant of the protective device comprises one selected from a group consisting of a transparent resin, an opaque resin and a semitransparent resin.

8. The side view light emitting diode according to claim 1, wherein the first or second electrical connector is a via.

9. The side view light emitting diode according to claim 8, wherein the first or second electrical connector is formed by filling metal powder and then sintering or reflowing the same.

10. The side view light emitting diode according to claim 1, wherein each of the first and second metal layers has at least a portion thereof exposed to the outside to supply external power to the light emitting diode chip.
